(19) United States
(12) Patent Application Publication
(10) Pub. No.: US 2020/0243355 A1
(43) Pub. Date: Jul. 30, 2020

(54) SUBSTRATE PROCESSING APPARATUS

(71) Applicant: Tokyo Electron Limited, Tokyo (JP)

(72) Inventor: Masatsugu Makabe, Kurokawa-gun (JP)

(21) Appl. No.: 16/774,066

(22) Filed: Jan. 28, 2020

(30) Foreign Application Priority Data
Jan. 28, 2019 (JP) 2019-012384

(51) Int. Cl. H01L 21/67; H01L 21/683; H01J 37/32

(52) U.S. Cl. CPC H01L 21/67109; H01L 21/67069; H01L 21/6833; H01J 2237/2001; H01J 37/3244; H01J 2237/334; H01J 37/32724

(57) ABSTRACT

A substrate processing apparatus includes a placing table, having a placing surface on which a processing target substrate is placed, provided with a gas supply line through which a heat transfer gas is supplied into a gap between the processing target substrate and the placing surface; and a gas supply system configured to generate the heat transfer gas to be supplied into the gap between the processing target substrate and the placing surface through the gas supply line by mixing a heat transfer gas having a relatively low temperature and a heat transfer gas having a relatively high temperature.

### CROSS-REFERENCE TO RELATED APPLICATION

This application claims the benefit of Japanese Patent Application No. 2019-012384 filed on Jan. 28, 2019, the entire disclosure of which is incorporated herein by reference.

### TECHNICAL FIELD

The various aspects and embodiments described herein pertain generally to a substrate processing apparatus.

### BACKGROUND

Conventionally, there is known a substrate processing apparatus configured to perform a substrate processing such as a plasma processing on a processing target substrate such as a semiconductor wafer. Such a substrate processing apparatus has, within a processing vessel in which, for example, a vacuum space is formed, a placing table configured to hold the processing target substrate. The placing table is provided with a gas supply line through which a heat transfer gas such as a helium gas is supplied into a gap between the processing target substrate and a placing surface on which the processing target substrate is placed. When the substrate processing is performed on the processing target substrate in the substrate processing apparatus, by supplying the heat transfer gas from the gas supply line into the gap between the processing target substrate and the placing surface of the placing table, the processing target substrate is adjusted to a preset temperature.

Patent Document 1: Japanese Patent Laid-open Publication No. 2017-126727

### SUMMARY

In one exemplary embodiment, a substrate processing apparatus includes a placing table, having a placing surface on which a processing target substrate is placed, provided with a gas supply line through which a heat transfer gas is supplied into a gap between the processing target substrate and the placing surface; and a gas supply system configured to generate the heat transfer gas to be supplied into the gap between the processing target substrate and the placing surface through the gas supply line by mixing a heat transfer gas having a relatively low temperature and a heat transfer gas having a relatively high temperature.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic cross sectional view illustrating a configuration of a plasma processing apparatus according to a first exemplary embodiment;

FIG. 2 is a diagram illustrating a configuration example of a placing table and a gas supply system according to the first exemplary embodiment;

FIG. 3 is a diagram illustrating a configuration example of a placing table and a gas supply system according to a second exemplary embodiment; and

FIG. 4 is a top view of the placing table according to the second exemplary embodiment, seen from above.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, various exemplary embodiments will be described with reference to the accompanying drawings. In the various drawings, same or corresponding parts will be assigned same reference numerals.

Conventionally, there is known a substrate processing apparatus configured to perform a substrate processing such as a plasma processing on a processing target substrate such as a semiconductor wafer. Such a substrate processing apparatus has, within a processing vessel in which, for example, a vacuum space is formed, a placing table configured to hold the processing target substrate. The placing table is provided with a gas supply line through which a heat transfer gas such as a helium gas is supplied into a gap between the processing target substrate and a placing surface on which the processing target substrate is placed. When the substrate processing is performed in the substrate processing apparatus, by supplying the heat transfer gas from the gas supply line into the gap between the processing target substrate and the placing surface of the placing table, heat exchange between the processing target substrate and the placing surface is performed, so that the processing target substrate is adjusted to an appropriate temperature for the substrate processing.

In the substrate processing apparatus, the heat transfer gas supplied into the gap between the processing target substrate and the placing surface of the placing table from the gas supply line is generally maintained at a regular temperature regardless of processing conditions for the substrate processing. If, however, the heat transfer gas supplied into the processing target substrate and the placing surface of the placing table is maintained at the regular temperature, efficiency of the heat exchange between the processing target substrate and the placing surface through the heat transfer gas may be deteriorated depending on the processing conditions of the substrate processing. As a consequence, it becomes difficult to adjust the temperature of the processing target substrate rapidly in a wide range. Thus, in the substrate processing apparatus, it is required to adjust the temperature of the processing target substrate rapidly in the wide range.

### First Exemplary Embodiment

[Configuration of Plasma Processing Apparatus]

First, the substrate processing apparatus will be explained. The substrate processing apparatus is configured to perform a plasma processing on the processing target substrate. In the present exemplary embodiment, description will be provided for an example case where the substrate processing apparatus is a plasma processing apparatus configured to perform plasma etching on a semiconductor wafer (hereinafter, simply referred to as “wafer”) as the processing target substrate.

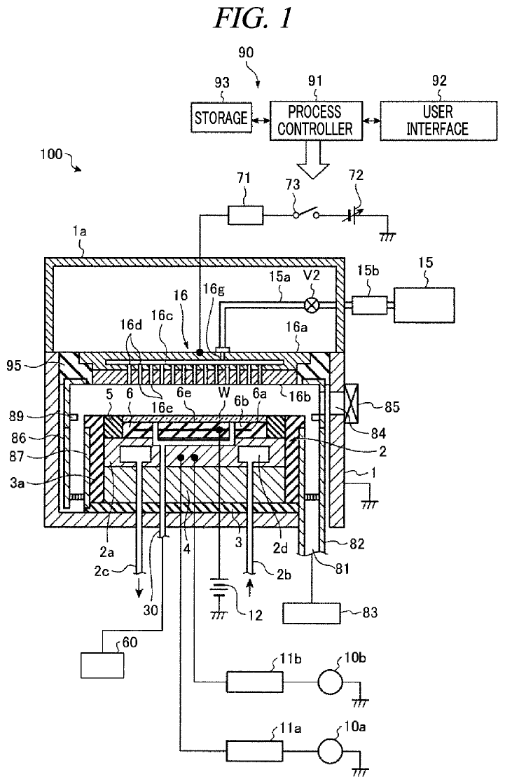

FIG. 1 is a schematic cross sectional view illustrating a configuration of a plasma processing apparatus according to a first exemplary embodiment. The plasma processing apparatus 100 has a processing vessel 1 which is hermetically sealed and is electrically grounded. The processing vessel 1 is of a cylindrical shape and is made of, by way of non-limiting example, aluminum. The processing vessel 1 forms a processing space in which plasma is formed. A placing table 2 configured to support the wafer W as the processing target substrate horizontally is provided within the processing vessel 1.

The placing table 2 includes a base 2a and an electrostatic chuck (ESC) 6. The base 2a is made of a conductive metal, for example, aluminum, and serves as a lower electrode. The electrostatic chuck 6 has a function of attracting the wafer W electrostatically. The placing table 2 is supported by a supporting table 4. The supporting table 4 is supported by a supporting member 3 which is made of, for example, quartz. Further, an edge ring 5 made of, by way of non-limiting example, single crystalline silicon is disposed on a peripheral portion of a top surface of the placing table 2. The edge ring 5 is also called a focus ring. Further, within the processing vessel 1, a cylindrical inner wall member 3a made of, by way of example, quartz is disposed to surround the placing table 2 and the supporting table 4.

A first RF power supply 10a and a second RF power supply 10b are connected to the base 2a via a first matching device 11a and a second matching device 11b, respectively. The first RF power supply 10a is for plasma formation and is configured to supply a high frequency power of a preset frequency to the base 2a of the placing table 2. Further, the second RF power supply 10b is for ion attraction (bias) and is configured to supply a high frequency power having a predetermined frequency lower than that of the first RF power supply 10a to the base 2a of the placing table 2. In this way, the placing table 2 is configured such that voltages are applicable thereto. Meanwhile, a shower head 16 serving as an upper electrode is disposed above the placing table 2, facing the placing table 2 in parallel. The shower head 16 and the placing table 2 serve as a pair of electrodes (upper electrode and lower electrode).

The electrostatic chuck 6 has a disk shape with a flat top surface, and this top surface is configured as a placing surface 6e on which the wafer W is placed. The electrostatic chuck 6 includes an insulator 6b and an electrode 6a embedded in the insulator 6b, and the electrode 6a is connected with a DC power supply 12. The wafer W is attracted to the electrostatic chuck 6 by a Coulomb force generated by a DC voltage applied to the electrode 6a from the DC power supply 12.

A coolant path 2d is formed within the placing table 2. A coolant inlet line 2b and a coolant outlet line 2c are connected to the coolant path 2d. The plasma processing apparatus 100 is configured to control the placing table 2 to a preset temperature by circulating an appropriate coolant, for example, cooling water in the coolant path 2d. Further, the placing table 2 is provided with a gas supply line 30 through which a heat transfer gas such as a helium gas is supplied into a gap between the wafer W and the placing surface 6e. The gas supply line 30 is connected to a gas supply system 60. The gas supply system 60 generates the heat transfer gas to be supplied into the gap between the wafer W and the placing surface 6e through the gas supply line 30. Accordingly, the heat transfer gas is supplied into the gap between the wafer W and the placing surface 6e through the gas supply line 30, so that heat exchange between the wafer W and the placing surface 6e is carried out by the heat transfer gas. With this configuration, the plasma processing apparatus 100 controls the wafer W attracted to and held on the top surface of the placing table 2 by the electrostatic chuck 6 to a predetermined temperature. Structures of the gas supply line 30 and the gas supply system 60 will be elaborated later.

The aforementioned shower head 16 is disposed at a ceiling portion of the processing vessel 1. The shower head 16 is equipped with a main body 16a and a ceiling plate 16b serving as an electrode plate. The shower head 16 is supported at an upper portion of the processing vessel 1 with an insulating member 95 therebetween. The main body 16a is made of a conductive material, for example, aluminum having an anodically oxidized top surface, and the ceiling plate 16b is detachably supported at a bottom of the main body 16a.

A gas diffusion space 16c is formed within the main body 16a. Further, a multiple number of gas through holes 16d are formed at a bottom portion of the main body 16a to be located at a lower portion of the gas diffusion space 16c. Further, the ceiling plate 16b is provided with gas discharge holes 16e which are formed through the ceiling plate 16b in a thickness direction thereof to be overlapped with the gas through holes 16d, respectively. With this configuration, a processing gas supplied into the gas diffusion space 16c is supplied into the processing vessel 1 through the gas through holes 16d and the gas discharge holes 16e while being distributed in a shower shape.

The main body 16a is provided with a gas inlet opening 16g through which the processing gas is introduced into the gas diffusion space 16c. One end of a gas supply line 15a is connected to the gas inlet opening 16g, and the other end of this gas supply line 15a is connected to a processing gas source (gas supply) 15 configured to supply the processing gas. The gas supply line 15a is provided with a mass flow controller (MFC) 15b and an opening/closing valve V2 in sequence from the upstream side. The processing gas for plasma etching is supplied from the processing gas source 15 into the gas diffusion space 16c through the gas supply line 15a. The processing gas is supplied from this gas diffusion space 16c into the processing vessel 1 through the gas through holes 16d and the gas discharge holes 16e while being distributed in the shower shape.

The aforementioned shower head 16 configured as the upper electrode is electrically connected with a variable DC power supply 72 via a low pass filter (LPF) 71. This variable DC power supply 72 is configured to turn on/off a power feed by an on/off switch 73. A current/voltage of the variable DC power supply 72 and an on/off operation of the on/off switch 73 are controlled by a controller 90 to be described later. Further, as will be described later, when plasma is formed in the processing space as the high frequency powers from the first RF power supply 10a and the second RF power supply 10b are applied to the placing table 2, the on/off switch 73 is turned on by the controller 90 when necessary, and a preset DC voltage is applied to the shower head 16 serving as the upper electrode.

A cylindrical grounding conductor la extends upwards from a sidewall of the processing vessel 1 to be higher than a height position of the shower head 16. This cylindrical grounding conductor la has a ceiling wall at a top portion thereof.

An exhaust port 81 is formed at a bottom of the processing vessel 1. The exhaust port 81 is connected with a first exhaust device 83 via an exhaust line 82. The first exhaust device 83 has a vacuum pump and is configured to decompress the processing vessel 1 to a preset vacuum level by operating the vacuum pump. Meanwhile, a carry-in/out opening 84 for the wafer W is formed at the sidewall of the processing vessel 1, and a gate valve 85 configured to open or close the carry-in/out opening 84 is provided at the carry-in/out opening 84.

A deposition shield 86 is provided along an inner wall surface of the sidewall of the processing vessel 1. The deposition shield 86 suppresses an etching byproduct (deposit) from adhering to the processing vessel 1. A conductive member (GND block) 89, which is connected such that a potential thereof with respect to the ground is controllable, is provided at the deposition shield 86 substantially on a level with the wafer W. The conductive member 89 is configured to suppress an abnormal discharge. Further, a deposition shield 87 extending along the inner wall member 3a is provided at a lower end portion of the deposition shield 86. The deposition shields 86 and 87 are provided in a detachable manner.

An overall operation of the plasma processing apparatus 100 having the above-described configuration is controlled by the controller 90. The controller 90 includes a process controller 91 having a CPU and configured to control the individual components of the plasma processing apparatus 100; a user interface 92; and a storage 93.

The user interface 92 includes a keyboard through which a process manager inputs commands to manage the plasma processing apparatus 100; a display configured to visually display an operational status of the plasma processing apparatus 100; and so forth.

The storage 93 stores therein a control program (software) for implementing various processings performed in the plasma processing apparatus 100 under the control of the process controller 91; and a recipe in which processing condition data or the like are stored. When necessary, a required recipe is retrieved from the storage 93 in response to an instruction from the user interface 92 and executed by the process controller 91, so that a required processing is performed in the plasma processing apparatus 100 under the control of the process controller 91. Further, the control program and the recipe including the processing condition data may be used by being stored in a computer-readable recording medium (for example, a hard disk, a CD, a flexible disk, a semiconductor memory, or the like). Alternatively, the control program and the recipe including the processing condition data may be used on-line by being transmitted from another apparatus through, for example, a dedicated line whenever necessary.

[Configuration of Placing Table and Gas Supply System]

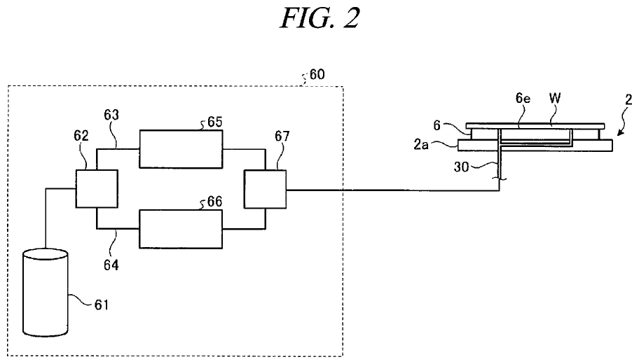

Now, referring to FIG. 2, a configuration of major components of the placing table 2 and the gas supply system 60 will be elaborated. FIG. 2 is a diagram illustrating an example configuration of the placing table 2 and the gas supply system 60 according to the first exemplary embodiment. The placing table 2 includes the base 2a and the electrostatic chuck 6. The electrostatic chuck 6 has a circular plate shape and is provided coaxially with the base 2a. The top surface of the electrostatic chuck 6 is configured as the placing surface 6e on which the wafer W is placed.

An end of the gas supply line 30 is placed at the placing surface 6e. The gas supply line 30 is a pipeline for supplying the heat transfer gas into the gap between the wafer W and the placing surface 6e. The gas supply line 30 is connected with the gas supply system 60. The gas supply system 60 generates the heat transfer gas to be supplied into the gap between the wafer W and the placing surface 6e through the gas supply line 30 by mixing a heat transfer gas having a relatively low temperature and a heat transfer gas having a relatively high temperature. To elaborate, the gas supply system 60 includes a heat transfer gas source 61, a distributor 62, adjusters 65 and 66 and a mixer 67.

The heat transfer gas source 61 is configured to supply a heat transfer gas of a room temperature to the distributor 62. The heat transfer gas of the room temperature may be, by way of example, but not limitation, a helium gas or an argon gas.

The distributor 62 is configured to distribute the heat transfer gas supplied from the heat transfer gas source 61 into a first path 63 and a second path 64.

The adjuster 65 is provided at the first path 63 and is configured to adjust the heat transfer gas distributed into the first path 63 by the distributor 62 to a first temperature. For example, the adjuster 65 cools the heat transfer gas distributed into the first path 63 to the first temperature lower than the room temperature by using a cooling mechanism such as a Peltier element. Further, the adjuster 66 is provided at the second path 64 and is configured to adjust the heat transfer gas distributed into the second path 64 by the distributor 62 to a second temperature higher than the first temperature. For example, the adjuster 66 heats the heat transfer gas distributed into the second path 64 to the second temperature higher than the room temperature by using a heating mechanism such as a heater. Here, though the adjuster 65 and the adjuster 66 are configured as different functional modules, the exemplary embodiment is not limited thereto, and the adjusters 65 and 66 may be implemented by a single functional module.

The mixer 67 is connected to the gas supply line 30. The mixer 67 is configured to generate the heat transfer gas to be supplied into the gap between the wafer W and the placing surface 6e through the gas supply line 30 by mixing the heat transfer gas adjusted to the first temperature with the adjuster 65 and the heat transfer gas adjusted to the second temperature with the adjuster 66.

In the plasma processing apparatus 100, the transfer gas supplied into the gap between the wafer W and the placing surface 6e of the placing table 2 through the gas supply line 30 is generally maintained at a regular temperature regardless of the processing conditions for the plasma processing. If the heat transfer gas supplied into the gap between the wafer W and the placing surface 6e of the placing table 2 is maintained at the regular temperature, the efficiency of the heat exchange between the wafer W and the placing surface 6e through the heat transfer gas may be deteriorated depending on a processing condition for the plasma processing. As a consequence, it becomes difficult to adjust the temperature of the wafer W rapidly in a wide range.

In view of this, in the plasma processing apparatus 100, the heat transfer gas to be supplied into the gap between the wafer W and the placing surface 6e is generated by using the gas supply system 60 configured to mix the heat transfer gas having the relatively low temperature and the heat transfer gas having the relatively high temperature. Accordingly, since the temperature of the heat transfer gas to be supplied into the gap between the wafer W and the placing surface 6e can be adjusted rapidly in a wide range, the heat exchange between the wafer W and the placing surface 6e through the heat transfer gas can be accelerated. As a result, in the plasma processing apparatus 100, the temperature of the wafer W can be adjusted rapidly in a wide range.

Further, the gas supply system 60 may vary a mixing ratio between the heat transfer gas having the relatively low temperature and the heat transfer gas having the relatively high temperature for each processing condition of the plasma processing upon the wafer W. Accordingly, even if the processing condition for the plasma processing is changed, the temperature of the heat transfer gas to be supplied into the gap between the wafer W and the placing surface 6e can be rapidly adjusted to a temperature suitable for the changed processing condition.

As described above, the plasma processing apparatus 100 according to the present exemplary embodiment is equipped with the placing table 2 and the gas supply system 60. The placing table 2 has the placing surface 6e on which the wafer W is placed, and is provided with the gas supply line 30 through which the heat transfer gas is supplied into the gap between the wafer W and the placing surface 6e. The gas supply system 60 generates the heat transfer gas to be supplied into the gap between the wafer W and the placing surface 6e through the gas supply line 30 by mixing the heat transfer gas having the relatively low temperature and the heat transfer gas having the relatively high temperature. Thus, the plasma processing apparatus 100 is capable of adjusting the temperature of the wafer W rapidly in a wide range.

### Second Exemplary Embodiment

Now, a second exemplary embodiment will be explained. The second exemplary embodiment is directed to variation of the structures of the placing table 2 and the gas supply system 60. Since a configuration of a plasma processing apparatus 100 according to the second exemplary embodiment is substantially identical to that of the plasma processing apparatus 100 shown in FIG. 1, same parts will be assigned same reference numerals, and redundant description will be omitted, while focusing on distinctive features.

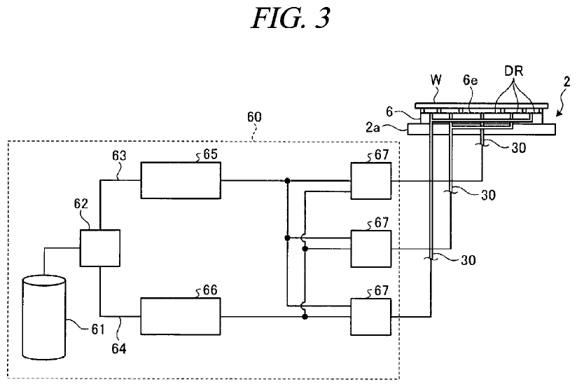

FIG. 3 is a diagram illustrating a configuration example of a placing table 2 and a gas supply system 60 according to the second exemplary embodiment. In the plasma processing apparatus 100 according to the second exemplary embodiment, a placing surface 6e of the placing table 2 is divided into multiple division regions DR by, for example, partition walls.

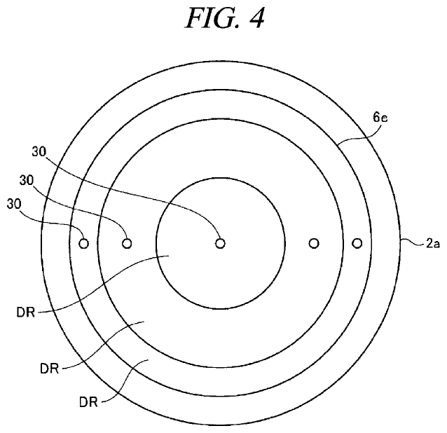

FIG. 4 is a top view of the placing table 2 according to the second exemplary embodiment, seen from above. In FIG. 4, the placing surface 6e of the placing table 2 is shown to have a circular plate shape. The placing surface 6e is divided into the multiple division regions DR depending on a distance from a center of the placing surface 6e.

Referring back to FIG. 3, the gas supply system 60 is equipped with multiple mixers 67 and multiple gas supply lines 30 corresponding to the multiple division regions DR of the placing surface 6e, respectively. For example, as depicted in FIG. 3 and FIG. 4, the gas supply lines 30 are disposed at a circular central region of the placing surface 6e and a plurality of concentric peripheral regions surrounding the central region, respectively, and these gas supply lines 30 are connected to the mixers 67, respectively. Each of branch paths branched from a first path 63 and each of branch paths branched from the second path 64 are connected to a corresponding one of the mixers 67, and a heat transfer gas adjusted to a first temperature by an adjuster 65 and a heat transfer gas adjusted to a second temperature by the adjuster 66 are supplied into each mixer 67.

The multiple mixers 67 generate multiple heat transfer gases by mixing the heat transfer gas adjusted to the first temperature with the adjuster 65 and the heat transfer gas adjusted to the second temperature with the adjuster 66 at mixing ratios set for the mixers 67 individually. By way of example, the multiple mixers 67 generate the multiple heat transfer gases having different temperatures by mixing the heat transfer gas adjusted to the first temperature and the heat transfer gas adjusted to the second temperature at different mixing ratios set for the mixers 67. Then, the multiple mixers 67 supply, through the corresponding gas supply lines 30, the multiple transfer gases into gaps between a wafer W and the placing surface 6e, which are formed to correspond to the multiple division regions DR of the placing surface 6e, respectively. Accordingly, temperatures of the heat transfer gases to be supplied into the gaps between the wafer W and the placing surface 6e through the gas supply lines 30 are controlled individually, so that the temperature of the wafer W is adjusted for each division region DR individually.

As described above, in the plasma processing apparatus 100 according to the second exemplary embodiment, the placing surface 6e is divided into the multiple division regions DR. Further, the multiple mixers 67 and the multiple gas supply lines 30 are provided to correspond to the multiple division regions DR of the placing surface 6e, respectively. The multiple mixers 67 generate the multiple heat transfer gases by mixing the heat transfer gas adjusted to the first temperature and the heat transfer gas adjusted to the second temperature at the mixing ratios set for the mixers 67 individually. Then, the multiple mixers 67 supply, through the corresponding gas supply lines 30, the multiple transfer gases into the gaps between the wafer W and the placing surface 6e, which are formed to correspond to the multiple division regions DR of the placing surface 6e, respectively. Thus, the plasma processing apparatus 100 is capable of adjusting the temperature of the wafer W for each division region DR rapidly in a wide range.

Furthermore, it should be noted that the above-described exemplary embodiments are illustrative in all aspects and are not anyway limiting. The above-described exemplary embodiments may be omitted, replaced and modified in various ways without departing from the scope and the spirit of claims.

By way of example, in the above-described exemplary embodiments, the mixer 67 is disposed at an outside of the placing table 2. However, the present disclosure is not limited thereto, and the mixer 67 may be disposed within the placing table 2 (for example, the base 2a). With such a configuration, the heat transfer gas adjusted to the first temperature and the heat transfer gas adjusted to the second temperature can be mixed at a position close to the gap between the wafer W and the placing surface 6e, so that the efficiency of the heat exchange between the wafer W and the placing surface 6e through the heat transfer gas can be improved.

Further, the above exemplary embodiments have been described for the example where the heat transfer gas source 61 supplies the heat transfer gas of the room temperature. However, the present disclosure is not limited thereto, and the heat transfer gas source 61 may supply, for example, a gas previously cooled to a temperature lower than the room temperature. The gas previously cooled to the temperature lower than the room temperature may be, by way of example, a nitrogen gas produced by vaporizing liquid nitrogen. By using the gas previously cooled to the temperature lower than the room temperature, the configuration of the adjusters 65 and 66 can be simplified. For example, the adjusters 65 and 66 can be composed of only the heating mechanism such as the heater, and the cooling mechanism such as the Peltier element can be omitted.

Furthermore, the first exemplary embodiment has been described for the example where the gas supply system 60 generates the heat transfer gas having the relatively low temperature and the heat transfer gas having the relatively high temperature by using the single heat transfer gas source 61 and mix these two heat transfer gases. However, the present disclosure is not limited thereto. By way of example, the gas supply system 60 may generate a heat transfer gas to be supplied into the gap between the wafer W and the placing surface 6e by mixing a heat transfer gas having a relatively low temperature and a heat transfer gas having a relatively high temperature respectively supplied from two or more heat transfer gas sources.

In addition, the above exemplary embodiments have been described for the example where the plasma processing apparatus 100 is configured to perform the plasma etching. However, the present disclosure is not limited thereto. For example, the plasma processing apparatus 100 may be configured to perform film formation or film modification.

Moreover, in the above-described exemplary embodiments, the plasma processing apparatus 100 is the plasma processing apparatus using capacitively coupled plasma (CCP). However, the exemplary embodiments may be also applicable to plasma processing apparatuses using various other kinds of plasma sources. By way of non-limiting example, the plasma sources applied to the plasma processing apparatus include inductively coupled plasma (ICP), radial line slot antenna (RLSA), electron cyclotron resonance plasma (ECR), helicon wave plasma (HWP), and so forth.

According to the exemplary embodiment, it is possible to adjust the temperature of the processing target substrate rapidly in a wide range.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus, comprising:
a placing table, having a placing surface on which a processing target substrate is placed, provided with a gas supply line through which a heat transfer gas is supplied into a gap between the processing target substrate and the placing surface; and
a gas supply system configured to generate the heat transfer gas to be supplied into the gap between the processing target substrate and the placing surface through the gas supply line by mixing a heat transfer gas having a relatively low temperature and a heat transfer gas having a relatively high temperature.

2. The substrate processing apparatus of claim 1,
wherein the gas supply system comprises:
a heat transfer gas source;
a distributor configured to distribute the heat transfer gas supplied from the heat transfer gas source into a first path and a second path;
an adjuster configured to adjust the heat transfer gas distributed into the first path to a first temperature and adjust the heat transfer gas distributed into the second path to a second temperature higher than the first temperature; and
a mixer connected to the gas supply line and configured to generate the heat transfer gas to be supplied into the gap between the processing target substrate and the placing surface through the gas supply line by mixing the heat transfer gas adjusted to the first temperature and the heat transfer gas adjusted to the second temperature.

3. The substrate processing apparatus of claim 2,
wherein the mixer is disposed within the placing table.

4. The substrate processing apparatus of claim 2,
wherein the placing surface is divided into multiple division regions,
the mixer includes multiple mixers and the gas supply line includes multiple gas supply lines, and the multiple mixers and the multiple gas supply lines are provided to correspond to the multiple division regions, respectively, and
the multiple mixers generate multiple heat transfer gases by mixing the heat transfer gas adjusted to the first temperature and the heat transfer gas adjusted to the second temperature at mixing ratios set for the multiple mixers individually, and supply the multiple heat transfer gases into gaps between the processing target substrate and the placing surface, which are formed to correspond to the multiple division regions, respectively, through the multiple gas supply lines.

5. The substrate processing apparatus of claim 2,
wherein the heat transfer gas source supplies the heat transfer gas cooled to a temperature lower than a room temperature.

6. The substrate processing apparatus of claim 3,
wherein the placing surface is divided into multiple division regions,
the mixer includes multiple mixers and the gas supply line includes multiple gas supply lines, and the multiple mixers and the multiple gas supply lines are provided to correspond to the multiple division regions, respectively, and
the multiple mixers generate multiple heat transfer gases by mixing the heat transfer gas adjusted to the first temperature and the heat transfer gas adjusted to the second temperature at mixing ratios set for the multiple mixers individually, and supply the multiple heat transfer gases into gaps between the processing target substrate and the placing surface, which are formed to correspond to the multiple division regions, respectively, through the multiple gas supply lines.

7. The substrate processing apparatus of claim 6,
wherein the heat transfer gas source supplies the heat transfer gas cooled to a temperature lower than a room temperature.
